(19) United States
(12) Patent Application Publication
(10) Pub. No.: US 2026/0206526 A1
(43) Pub. Date: Jul. 16, 2026

(54) SUBSTRATE PROCESSING APPARATUS, INFORMATION PROCESSING APPARATUS, AND INFORMATION PROCESSING METHOD

(71) Applicant: Tokyo Electron Limited, Tokyo (JP)

(72) Inventor: Atsushi SHIGENOBU, Yamanashi (JP)

(21) Appl. No.: 19/441,410

(22) Filed: Jan. 6, 2026

(30) Foreign Application Priority Data
Jan. 16, 2025 (JP) 2025-006225

(51) Int. Cl. H10P 72/00

(52) U.S. Cl. CPC H10P 72/0602; H10P 72/0604

(57) ABSTRACT

A substrate processing apparatus includes: a heat treatment container; a substrate holder; a transfer device that includes a temperature sensor, and moves between a measurement position for measuring a temperature of a substrate held by the substrate holder and a standby position; and a control unit that controls an operation of the transfer device. The control unit includes: a measurement control unit that moves the transfer device between the measurement position and the standby position, and causes the temperature sensor to measure a temperature change of the substrate over time; a time characteristic calculation unit that calculates a time characteristic of the temperature of the substrate; a cooling time calculation unit that calculates a cooling time until the temperature of the substrate becomes equal to or less than a threshold value; and a timing determination unit that determines a timing to start transfer of the substrates from the substrate holder.

### CROSS REFERENCES TO RELATED APPLICATIONS

This application is based on and claims priority from Japanese Patent Application No. 2025-006225, filed on Jan. 16, 2025, with the Japan Patent Office, the disclosure of which is incorporated herein in its entirety by reference.

### TECHNICAL FIELD

The present disclosure relates to a substrate processing apparatus, an information processing apparatus, and an information processing method.

### BACKGROUND

A vertical heat treatment apparatus has been known that includes a vertically elongated heat treatment furnace, and performs heat treatment while accommodating a wafer boat in the heat treatment furnace in a state where a plurality of wafers is placed on the wafer boat, thereby heating the wafers. In the vertical heat treatment apparatus, after the heat treatment is performed on the wafers, the wafer boat is unloaded from the heat treatment furnace. Then, after a predetermined cooling time elapses, a transfer device transfers the wafers from the wafer boat into a front-opening unified pod (FOUP) to collect the wafers. The cooling time is the sum of the time required for the wafers to cool to a predetermined temperature (e.g., 80° C.), and a predetermined waiting time (margin time).

For example, Japanese Patent Laid-Open Publication No. 2019-047111 describes a technology of shortening a collection time and achieving improvement in the productivity because there is a problem in that the time required for wafer conveyance includes a predetermined waiting time, and the time for wafer collection is lengthened by the amount of the waiting time.

### SUMMARY

According to an aspect of the present disclosure, a substrate processing apparatus includes: a heat treatment container; a substrate holder capable of being accommodated in the heat treatment container while holding a substrate; a transfer device that includes a temperature sensor, and moves between a measurement position for measuring a temperature of the substrate held by the substrate holder unloaded from the heat treatment container and a standby position separated from the measurement position; and a control unit that controls an operation of the transfer device. The control unit includes: a measurement control unit that moves the transfer device between the measurement position and the standby position, and causes the temperature sensor to measure a temperature change of the substrate over time after the substrate holder is unloaded from the heat treatment container; a time characteristic calculation unit that calculates, based on the measurement result of the temperature change of the substrate over time, a time characteristic of the temperature of the substrate after the substrate holder is unloaded from the heat treatment container; a cooling time calculation unit that calculates, based on the time characteristic of the temperature of the substrate, a cooling time until the temperature of the substrate becomes equal to or less than a threshold value after the substrate holder is unloaded from the heat treatment container; and a timing determination unit that determines, based on the cooling time characteristic, a timing to start transfer of the substrates from the substrate holder.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic configuration diagram of an example of a substrate processing apparatus 1 according to the present embodiment.

FIG. 2 is a schematic plan view of an example of the substrate processing apparatus 1 according to the present embodiment.

FIG. 3 is a flow chart of an example of a transfer sequence of wafers W in the substrate processing apparatus 1.

FIG. 4 is a schematic view illustrating an example of an operation of measuring the temperature of the wafer W in a non-contact manner, in a transfer sequence of the wafers W in the substrate processing apparatus 1.

FIG. 5 is a functional block diagram of an example of a control unit 100 according to the present embodiment.

FIG. 6 is a flow chart of an example of processing in which the substrate processing apparatus 1 according to the present embodiment determines the timing to start transfer of the wafers W from a wafer boat 50.

FIG. 7 is a view illustrating an example in relation to the temperatures of the wafer W from the start of the temperature measurement on the heat-treated wafer W until the wafer W becomes unloadable, and the change of the temperature measured by a temperature sensor 67 over time.

FIG. 8 is a functional block diagram of an example of the control unit 100 according to the present embodiment.

FIGS. 9A to 9C are views illustrating an example of the evaluation result of the substrate processing apparatus 1 according to the present embodiment.

FIG. 10 is a hardware configuration diagram of an example of a computer 500.

FIG. 11 is a configuration diagram of an example of a substrate processing system according to the present embodiment.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, the present embodiment will be described with reference to drawings. In the present embodiment, descriptions will be made on an example in which a substrate processing apparatus is a vertical heat treatment apparatus.

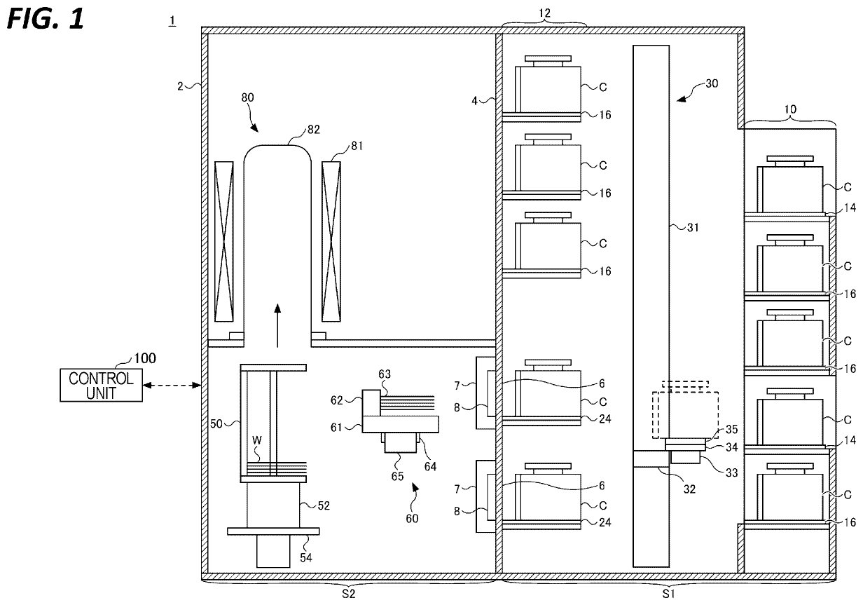

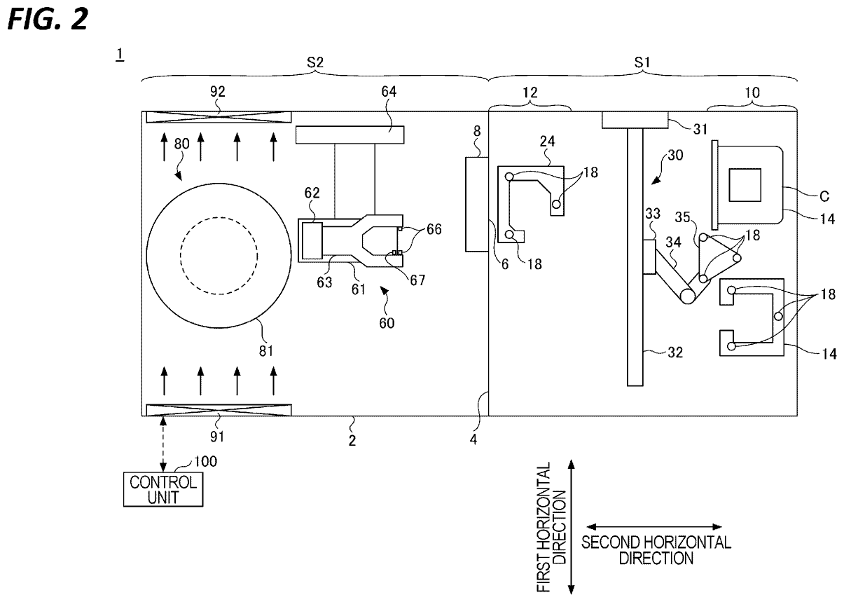

FIG. 1 is a schematic configuration diagram of an example of a substrate processing apparatus 1 according to the present embodiment. FIG. 2 is a schematic plan view of an example of the substrate processing apparatus 1 according to the present embodiment. Also, for convenience of explanation, FIG. 2 illustrates a state where no carrier C is placed on one of load ports 14 and a front-opening interface mechanical standard (FIMS) port 24 in FIG. 1.

In the configuration, the substrate processing apparatus 1 is housed in a housing 2. A carrier transfer area S1 and a wafer transfer area S2 are formed inside the housing 2. The carrier transfer area S1 and the wafer transfer area S2 are separated by a partition wall 4. The partition wall 4 is provided with a transfer port 6 through which the carrier transfer area S1 and the wafer transfer area S2 communicate with each other, and wafers W are transferred.

The transfer port 6 is opened/closed by a door mechanism 8 based on the FIMS. A driving mechanism of a lid opening/closing device 7 is connected to the door mechanism 8. Due to the driving mechanism, the door mechanism 8 is configured to be movable in the front-rear direction and the up-down direction, and opens/closes the transfer port 6.

Hereinafter, the arrangement direction of the carrier transfer area S1 and the wafer transfer area S2 is set to a front-rear direction (corresponding to a second horizontal direction to be described below), and the horizontal direction perpendicular to the front-rear direction is set to a left-right direction (corresponding to a first horizontal direction to be described below).

The carrier transfer area S1 is an area of atmospheric air. The carrier transfer area S1 is an area where carriers C are transferred between elements (to be described below) within the substrate processing apparatus 1, are loaded into the substrate processing apparatus 1 from the outside, or are unloaded from the substrate processing apparatus 1 to the outside. The carrier C stores semiconductor wafers (hereinafter referred to as “wafers W”) as transfer targets. The wafer W is an example of a substrate. The carrier C may be, for example, a front-opening unified pod (FOUP). As the cleanliness inside the FOUP is maintained at a predetermined level, adhesion of foreign substances to the surface of the wafer W or formation of a natural oxide film may be prevented.

The carrier transfer area S1 includes a first transfer area 10, and a second transfer area 12 located behind the first transfer area 10 (e.g., on a side of the wafer transfer area S2).

As an example, in the first transfer area 10, there are two-level upper and lower stages, and at each stage, two load ports 14 are provided on the left and right sides. The load port 14 is a loading stage that accommodates the carrier C when the carrier C is loaded into the substrate processing apparatus 1. The load port 14 is provided at a place where the wall of the housing 2 is open. The load port 14 allows access to the substrate processing apparatus 1 from the outside.

Specifically, by a transfer device (not illustrated) provided outside the substrate processing apparatus 1, the carrier C can be loaded onto and placed on the load port 14, and the carrier C can be unloaded from the load port 14 to the outside.

Also, since the load ports 14 exist in two-level upper and lower stages, the carriers C are allowed to be loaded and unloaded at both sides. A stocker 16 may be provided below the load port 14 to store the carrier C. Positioning pins 18 for positioning the carrier C are provided at, for example, three locations, on the surface of the load port 14 on which the carrier C is placed. Also, in a state where the carrier C is placed on the load port 14, the load port 14 may be configured to be movable in the front-rear direction.

Two FIMS ports 24 are disposed side by side in the up-down direction in the lower portion of the second transfer area 12. The FIMS port 24 is a holding stage that holds the carrier C when the wafers W in the carrier C are loaded and unloaded to/from a heat treatment furnace 80 (to be described below) in the wafer transfer area S2. The FIMS port 24 is configured to be movable in the front-rear direction. Like in the load port 14, positioning pins 18 for positioning the carrier C are provided at three locations on the surface of the FIMS port 24 on which the carrier C is placed.

A stocker 16 may be provided in the upper portion of the second transfer area 12 to store the carrier C. The stocker 16 is constituted by one or more shelves. Two or more carriers C may be placed in the left-right direction on each shelf. Also, the stocker 16 may also be provided in an area where the FIMS port 24 is not disposed, in the lower portion of the second transfer area 12.

A carrier transfer mechanism 30 that transfers the carriers C between the load port 14, the stocker 16, and the FIMS port 24 is provided between the first transfer area 10 and the second transfer area 12. The carrier transfer mechanism 30 includes a first guide 31, a second guide 32, a moving unit 33, an arm 34, and a hand 35. The first guide 31 is configured to extend in the up-down direction. The second guide 32 is connected to the first guide 31, and is configured to extend in the left-right direction (e.g., the first horizontal direction). The moving unit 33 is configured to move in the left-right direction by being guided by the second guide 32. The arm 34 has one joint and two arms and is provided on the moving unit 33. The hand 35 is provided at the distal end of the arm 34. Pins 18 for positioning the carrier C are provided at three locations of the hand 35.

The wafer transfer area S2 is an area where the wafers W are taken out of the carrier C and various processes are performed. The wafer transfer area S2 is under an inert gas atmosphere, for example, a nitrogen (N₂) gas atmosphere so as to prevent an oxide film from being formed on the wafer W. The vertical heat treatment furnace 80 having an open furnace port at the lower end thereof is provided in the wafer transfer area S2.

The heat treatment furnace 80 has a cylindrical heat treatment container 82 made of quartz, which can accommodate the wafers W and is configured to perform heat treatment of the wafers W. A cylindrical heater 81 is disposed around the heat treatment container 82. The heat treatment furnace 80 performs heat treatment on the accommodated wafers W through heating of the heater 81. A shutter (not illustrated) is provided below the heat treatment container 82.

The shutter is a door for covering the lower end of the heat treatment furnace 80 after a wafer boat 50 is unloaded from the heat treatment furnace 80 and before the next wafer boat 50 is loaded. Below the heat treatment furnace 80, the wafer boat 50 that is a substrate holder is placed on a lid 54 via a heat insulating cylinder 52.

The wafer boat 50 is made of, for example, quartz, and is configured to substantially horizontally hold the wafers W separated by a predetermined interval in the up-down direction. The lid 54 is supported by a lifting mechanism (not illustrated), and the lifting mechanism allows the wafer boat 50 to be loaded or unloaded to/from the heat treatment furnace 80.

A wafer transfer device 60 is provided between the wafer boat 50 and the transfer port 6. The wafer transfer device 60 transfers the wafers W between the carrier C held on the FIMS port 24 and the wafer boat 50.

The wafer transfer device 60 has a guide mechanism 61, a moving body 62, a fork 63, a lifting mechanism 64, and a rotation mechanism 65. The guide mechanism 61 is attached to the lifting mechanism 64 that extends in the vertical direction, and then is movable vertically by the lifting mechanism 64 and is rotatable by the rotation mechanism 65. The moving body 62 is provided on the guide mechanism 61 such that it is movable forward and backward along the longitudinal direction. The fork 63 is a transfer device attached via the moving body 62, and a plurality of forks (e.g., five forks) is provided. The wafer transfer device 60 may have the plurality of forks 63 so that the plurality of wafers W may be transferred at once. Also, there may be one fork 63.

A position detection sensor 66 is provided on the inner side surface of the tip of the fork 63. The position detection sensor 66 is, for example, a pair of opposing photodetectors. The position detection sensor 66 may detect, for example, whether the wafer W has protruded from the wafer boat 50, or whether the wafer W has shifted in position when the wafer W is held in the wafer boat 50.

Also, a temperature sensor 67 is provided inside the tip of the fork 63. The temperature sensor 67 measures the temperature in the vicinity of the fork 63. For example, the temperature sensor 67 may measure the temperature of the wafer W in a non-contact manner when the fork 63 is inserted between two adjacent wafers W among the wafers W held in the wafer boat 50.

Although various thermocouples may be used for the temperature sensor 67, it is desirable to use an ultra-fine wire thermocouple (e.g., having a tip wire diameter of 25μm) from the viewpoint of fast response and high-accuracy temperature measurement. Also, a resistance temperature detector may also be used for the temperature sensor 67. The temperature sensor 67 may be provided at a location other than the inside of the tip of the fork 63.

A fan filter unit (FFU) 91 is provided on one side wall of the wafer transfer area S2, and a gas suction unit 92 is provided on the other side wall facing the side wall where the FFU 91 is provided. The FFU 91 supplies gas (e.g., inert gas such as N₂ gas) purified through a filter, to the wafer transfer area S2. The gas suction unit 92 sucks the purified gas supplied from the FFU 91 to the wafer transfer area S2. A horizontal gas flow (see, e.g., the arrows in FIG. 2) is formed in the wafer transfer area S2. Due to this gas flow, the wafer transfer area S2 is kept clean and a temperature rise is suppressed. Also, due to this gas flow, the heat-treated wafers W, which are held in the wafer boat 50 unloaded from the heat treatment furnace 80, are cooled. Also, in addition to the FFU 91 and the gas suction unit 92, or instead of the FFU 91 and the gas suction unit 92, a cooling mechanism for cooling the heat-treated wafers W, such as a water cooling unit, may be provided.

As illustrated in FIG. 1 and FIG. 2, the substrate processing apparatus 1 is provided with a control unit 100 that controls the entire substrate processing apparatus 1. The control unit 100 controls the operation of various devices within the substrate processing apparatus 1 in accordance with a recipe, such as a film formation recipe, so that heat treatment is performed under various processing conditions specified in the recipe. Also, by receiving signals from various sensors provided in the substrate processing apparatus 1, the control unit 100 controls a sequence such as a transfer sequence of the wafer W, in which, for example, the position of the wafer W is grasped, and then the process proceeds. Furthermore, the control unit 100 may perform, for example, feedback control required for appropriately performing substrate processing, by, for example, sensor values measured by various sensors provided in the substrate processing apparatus 1.

The control unit 100 includes, for example, a processor, a memory, an auxiliary storage device, and a communication device. The processor is a computing unit such as a central processing unit (CPU) or a graphics processing unit (GPU). The memory is a storage unit such as a read only memory (ROM) or a random access memory (RAM). The control unit 100 may be configured as a microcomputer that installs a program for controlling the substrate processing apparatus 1 from a storage medium in which the program is stored, and executes control of the substrate processing apparatus 1. Also, the control unit 100 may be configured as an electronic circuit such as an application specific integrated circuit (ASIC).

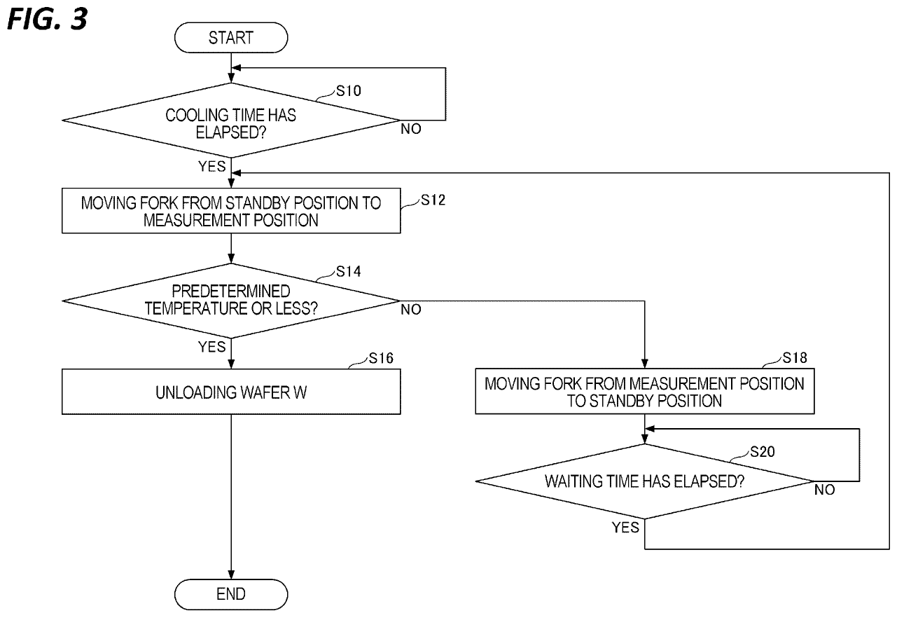

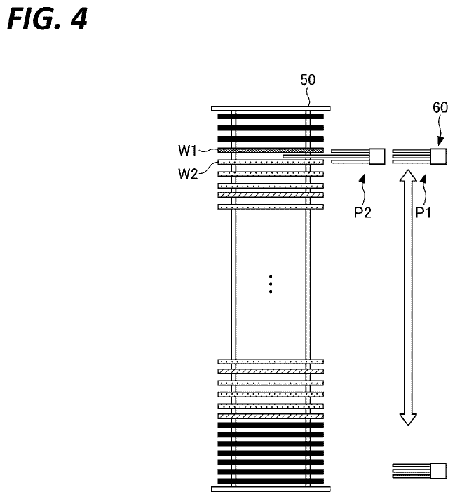

Next, a transfer sequence of the wafers W will be described with reference to FIG. 3 and FIG. 4, in which the heat-treated wafers W are collected into the FOUP.

FIG. 3 is a flow chart of an example of a transfer sequence of the wafers W in the substrate processing apparatus 1. FIG. 4 is a schematic view illustrating an example of an operation of measuring the temperature of the wafer W in a non-contact manner, in a transfer sequence of the wafers W in the substrate processing apparatus 1.

After the heat treatment is completed, the wafer boat 50 holding the wafers W is unloaded from the heat treatment furnace 80. Since the wafers W are at a high temperature immediately after the heat treatment is completed, the wafers W are put into a waiting state on the wafer boat 50, and the wafers W are cooled by a gas flow formed by the FFU 91 and the gas suction unit 92.

In step S10, the control unit 100 determines whether a predetermined time (hereinafter, referred to as a cooling time) has elapsed since the cooling of the wafers W began. Also, the cooling time may be determined according to, for example, conditions of heat treatment, and may be, for example, 5 min.

The control unit 100 repeats processing of step S10 until it is determined that the cooling time has elapsed. When it is determined that the cooling time has elapsed, the control unit 100 performs processing of step S12.

In step S12, the control unit 100 controls the operation of the wafer transfer device 60 so as to move the fork 63 from a standby position P1 to a measurement position P2. The measurement position P2 is a position at which the temperature of a wafer W1 (as a temperature measurement target) is measured. For example, as illustrated in FIG. 4, the measurement position P2 may be a position between the wafer W1 that is a temperature measurement target, and a wafer W2 located one level below the wafer W1 among the wafers W held in the wafer boat 50. The standby position P1 is a position separated from the measurement position P2, and may be, for example, a position on the side of the wafer boat 50, at the same height as the measurement position P2 as illustrated in FIG. 4.

In step S14, the control unit 100 determines whether the temperature of the wafer W1 (as the temperature measurement target) obtained by measurement during a first period (e.g., 5 sec) is equal to or less than a predetermined temperature (e.g., a threshold value). The first period is determined according to the characteristics of the temperature sensor 67. The threshold value may be determined according to, for example, the heat resistance of materials constituting the wafer transfer device 60, the FOUP, or the like.

When it is determined that the temperature is equal to or less than the predetermined temperature, the control unit 100 controls the operation of the wafer transfer device 60 so as to unload the plurality of wafers W held in the wafer boat 50. The wafer transfer device 60 unloads the plurality of wafers W at once from the wafer boat 50 by using the plurality of forks 63, and transfers the wafers W into the FOUP.

In step S14, when it is determined that the temperature is greater than the predetermined temperature, the control unit 100 performs processing in step S18. In step S18, the control unit 100 controls the operation of the wafer transfer device 60 so as to move the fork 63 from the measurement position P2 to the standby position P1.

In step S20, the control unit 100 determines whether a waiting time has elapsed since the fork 63 was moved to the standby position P1 by processing in step S18. The waiting time is determined according to the characteristics of the temperature sensor 67. The control unit 100 repeats processing in step S20 until it is determined that the waiting time has elapsed. When it is determined that the waiting time has elapsed, the control unit 100 returns to the processing in step S12. That is, the control unit 100 controls again the operation of the wafer transfer device 60 so as to move the fork 63 from the standby position P1 to the measurement position P2.

In the wafer W transfer sequence described with reference to FIG. 3 and FIG. 4, a waiting state is made until a fixed cooling time elapses in step S10 of FIG. 3 because there is a possibility of melting if the temperature sensor 67 of the fork 63 is brought close to a high-temperature wafer W immediately after completion of heat treatment. However, when the temperature of the heat treatment (e.g., the film formation temperature) is low, the cooling time may be too long, and then there is a possibility that the productivity of the substrate processing apparatus 1 may be reduced. Also, if the temperature of the heat treatment is high, the cooling time may be too short, and then there is a possibility that the temperature sensor 67 of the fork 63 may fail. In many cases, the cooling time was set assuming the maximum heat treatment temperature in consideration of the failure risk of the temperature sensor 67 of the fork 63.

Therefore, the substrate processing apparatus 1 according to the present embodiment predicts a cooling time as follows. Over the cooling time, the temperature of the wafer W unloaded from the heat treatment furnace 80 becomes equal to or less than an allowable temperature (e.g., a threshold value) at which the transfer of the wafers W begins.

Since the substrate processing apparatus 1 according to the present embodiment may appropriately determine the timing to start transfer of the wafers W, it is possible to suppress the productivity from being reduced due to an extremely long cooling time, and to suppress the temperature sensor 67 of the fork 63 from failing due to an extremely short cooling time.

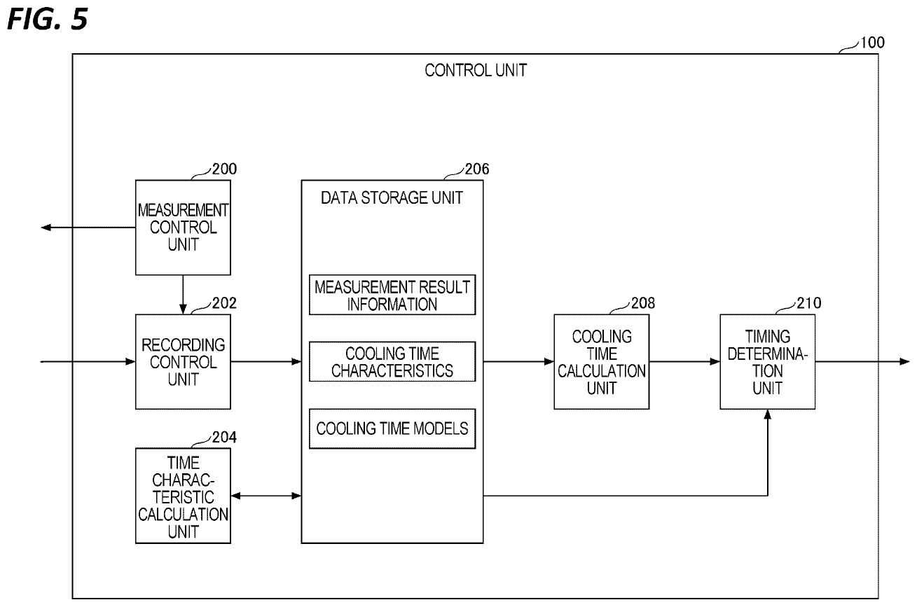

The control unit 100 of the substrate processing apparatus 1 according to the present embodiment is realized by, for example, functional blocks illustrated in FIG. 5. FIG. 5 is a functional block diagram of an example of the control unit 100 according to the present embodiment. Also, in the illustration of the functional block diagram of FIG. 5, components that are unnecessary for explaining the present embodiment are appropriately omitted.

In the control unit 100 in FIG. 5, a program for the control unit 100 is executed so as to implement a measurement control unit 200, a recording control unit 202, a time characteristic calculation unit 204, a data storage unit 206, a cooling time calculation unit 208, and a timing determination unit 210.

The measurement control unit 200 moves the fork 63 between the measurement position and the standby position, and causes the temperature sensor 67 to measure the temperature change of the wafer W over time after the wafer boat 50 is unloaded from the heat treatment container 82.

The recording control unit 202 stores the measurement result that is measured by the temperature sensor 67 under the control of the measurement control unit 200, as measurement result information, in the data storage unit 206. The time characteristic calculation unit 204 calculates the time characteristic of the temperature of the wafer W (hereinafter, referred to as a cooling time characteristic) after the wafer boat 50 is unloaded from the heat treatment container 82, based on the measurement result of the temperature change of the wafer W over time after the wafer boat 50 is unloaded from the heat treatment container 82. Also, detailed contents of calculation performed by the time characteristic calculation unit 204 will be described later.

The data storage unit 206 stores measurement result information, cooling time characteristics, and cooling time models. Also, the cooling time model will be described later.

The cooling time calculation unit 208 calculates the cooling time until the temperature of the wafer W becomes equal to or less than the threshold value after the wafer boat 50 is unloaded from the heat treatment container 82, based on the cooling time characteristic calculated by the time characteristic calculation unit 204.

The timing determination unit 210 determines the timing to start transfer of the wafers W from the wafer boat 50 based on the cooling time calculated by the cooling time calculation unit 208. Before the cooling time is calculated by the cooling time calculation unit 208, when the temperature of the wafer W measured by the temperature sensor 67 becomes equal to or less than the threshold value, the timing determination unit 210 causes the fork 63 to start the transfer of the wafers W from the wafer boat 50. Once the cooling time is calculated by the cooling time calculation unit 208, after waiting for the cooling time, the timing determination unit 210 causes the fork 63 to start the transfer of the wafers W from the wafer boat 50.

When the timing determination unit 210 determines the timing to start transfer of the wafers W from the wafer boat 50 based on the cooling time, the measurement control unit 200 does not cause the temperature sensor 67 to measure the temperature change of the wafer W over time after the wafer boat 50 is unloaded from the heat treatment container 82.

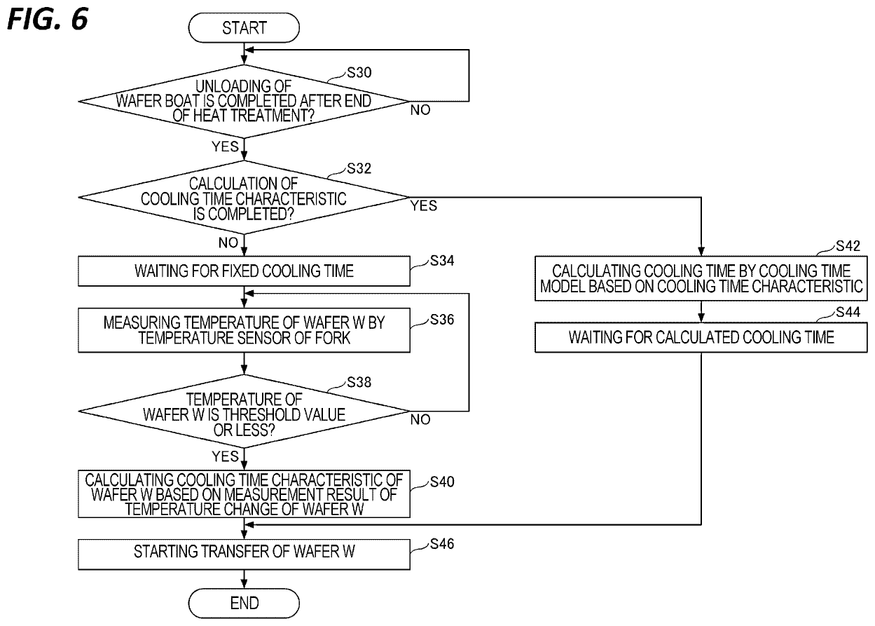

FIG. 6 is a flow chart of an example of processing in which the substrate processing apparatus 1 according to the present embodiment determines the timing to start transfer of the wafers W from the wafer boat 50.

The measurement control unit 200 repeats processing of step S30 until the unloading of the wafer boat 50 from the heat treatment container 82 is completed after the end of the heat treatment. When the unloading of the wafer boat 50 from the heat treatment container 82 is completed after the end of the heat treatment, the measurement control unit 200 determines whether calculation of a cooling time characteristic has been completed. For example, when heat treatments are executed according to the same recipe (hereinafter, referred to as Runs), if the calculation of the cooling time characteristic has not been completed in the previous Runs, the measurement control unit 200 determines that the calculation of the cooling time characteristic has not been completed.

When it is determined that the calculation of the cooling time characteristic has not been completed, in step S34, the measurement control unit 200 waits until the cooling time elapses after the start of the cooling of the wafers W as described in, for example, step S10 of FIG. 3.

In step S36, as described in, for example, step S12 of FIG. 3, the measurement control unit 200 controls the operation of the wafer transfer device 60 so as to move the fork 63 from the standby position P1 to the measurement position P2. This causes the temperature sensor 67 to measure the temperature of the wafer W held in the wafer boat 50.

In step S38, as described in, for example, step S14 of FIG. 3, the measurement control unit 200 determines whether the temperature of the wafer W obtained by measurement during a first period (e.g., 5 sec) is equal to or less than a predetermined temperature (e.g., a threshold value).

The measurement control unit 200 repeats processing in step S36 until the temperature of the wafer W obtained through the measurement of step S36 becomes equal to or less than the threshold value. Until the temperature of the wafer W obtained through the measurement of step S36 becomes equal to or less than the threshold value, the measurement control unit 200 repeats processing in step S36, while allowing the temperature sensor 67 to measure the temperature change of the wafer W over time after the wafer boat 50 is unloaded from the heat treatment container 82. Also, the temperature change of the wafer W over time after the wafer boat 50 is unloaded from the heat treatment container 82 is stored as measurement result information, in the data storage unit 206.

When the temperature of the wafer W obtained through the measurement of step S36 is equal to or less than the threshold value, the measurement control unit 200 performs processing in step S40. In step S40, the time characteristic calculation unit 204 calculates a cooling time characteristic based on the measurement result information stored in the data storage unit 206.

It is possible to calculate the cooling time characteristic by substituting, for example, the measurement result information stored in the data storage unit 206, into Equation (1) below. The cooling time characteristic is the value of “K” in Equation (1):

$$Temperature of wafer W = A * exp ( - k / K ) \qquad ( 1 )$$

A: Film formation temperature, k: Cooling time, K: Time constant (cooling time characteristic)

In this manner, the time characteristic calculation unit 204 may calculate the cooling time characteristic based on the measurement result information stored in the data storage unit 206. The time characteristic calculation unit 204 stores the cooling time characteristic in the data storage unit 206. Then, the process proceeds to step S46, and the timing determination unit 210 starts the transfer of the wafers W from the wafer boat 50.

In step S32, when it is determined that the calculation of the cooling time characteristic has been completed, the measurement control unit 200 proceeds to the processing of step S42. In step S42, based on the cooling time characteristic stored in the data storage unit 206, the cooling time calculation unit 208 calculates a cooling time until the temperature of the wafer W becomes equal to or less than the threshold value after the wafer boat 50 is unloaded from the heat treatment container 82, through the above-described cooling time model of Equation (1).

For example, by inputting a threshold value to the temperature of the wafer W in Equation (1), a film formation temperature to A, and a cooling time characteristic to K, it is possible to calculate the cooling time t until the temperature of the wafer W becomes equal to or less than the threshold value after the wafer boat 50 is unloaded from the heat treatment container 82.

Subsequent to step S42, the process proceeds to processing of step S44, and the timing determination unit 210 waits for the cooling time calculated in step S42. Subsequent to step S44, the process proceeds to processing of step S46, and the timing determination unit 210 starts the transfer of the wafers W from the wafer boat 50.

According to the processing of the flow chart in FIG. 6, in the first Run, it is necessary to let the temperature sensor 67 measure the temperature of the wafer W held in the wafer boat 50 after the fixed cooling time of step S34 has elapsed. However, in the second and subsequent Runs, without letting the temperature sensor 67 measure the temperature of the wafer W held in the wafer boat 50, it is possible to calculate the cooling time until the temperature of the wafer W becomes equal to or less than the threshold value after the wafer boat 50 is unloaded from the heat treatment container 82, based on the cooling time characteristic calculated in the first Run.

According to the present embodiment, in the second and subsequent Runs, there is no need to let the temperature sensor 67 measure the temperature of the wafer W held in the wafer boat 50, and the actuation for moving the fork 63 from the standby position P1 to the measurement position P2 is reduced, thereby improving the durability of the fork 63.

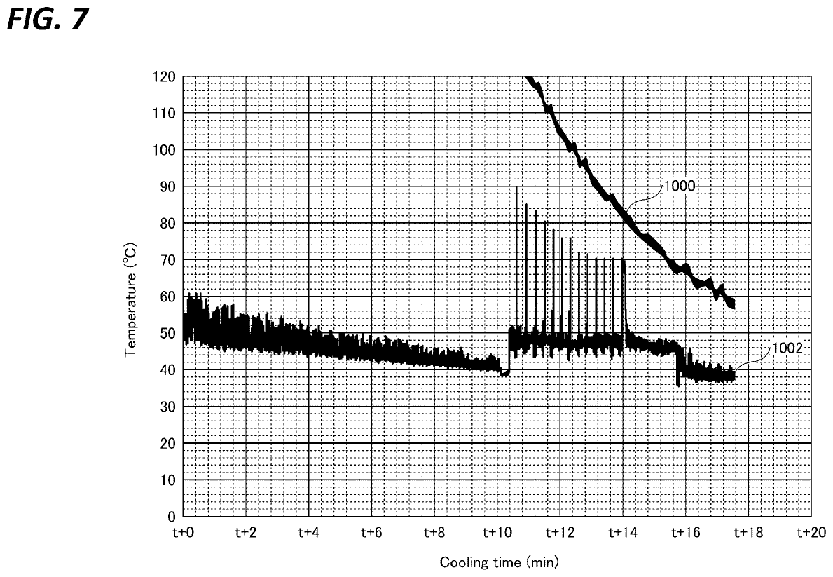

Next, in the substrate processing apparatus 1 according to the present embodiment, with reference to FIG. 7, descriptions will be made on the temperatures of the wafer W from the start of the temperature measurement on the heat-treated wafer W until the wafer W can be unloaded, and the change of the temperature measured by the temperature sensor 67 over time.

FIG. 7 is a view illustrating an example in relation to the temperatures of the wafer W from the start of the temperature measurement on the heat-treated wafer W until the wafer W can be unloaded, and the change of the temperature measured by the temperature sensor 67 over time.

In FIG. 7, the horizontal axis indicates the elapsed time (min) since unloading of the wafer boat 50 from the heat treatment furnace 80 began, and the vertical axis indicates the temperature (° C.). The graph line 1000 indicates the temperature of the wafer W. The graph line 1002 indicates the temperature measured by the temperature sensor 67. In the example of FIG. 7, the fixed cooling time is set to t+10 min.

As illustrated in FIG. 7, since the first to twelfth temperatures measured by the temperature sensor 67 at the measurement position P2 exceed 70° C. which is an example of the threshold value, the measurement of step S36 is repeated. Since the thirteenth temperature measured by the temperature sensor 67 at the measurement position P2 is equal to or less than 70° C. which is an example of the threshold value, the repetition of measurement of step S36 is stopped.

In this manner, in the present embodiment, the temperature sensor 67 may measure the temperature change of the wafer W over time after the wafer boat 50 is unloaded from the heat treatment container 82, in a non-contact manner. Also, when the threshold value is set to a low value, it is possible to increase the number of measurements of the temperature sensor 67 at the measurement position P2, thereby increasing the measurement result information. Then, the accuracy of the cooling time characteristic calculated in step S40 may be expected to be improved.

Also, in the flow chart of FIG. 6, whether to calculate the cooling time characteristic of the wafer W is determined according to whether the calculation of the cooling time characteristic has been completed. When a predetermined period of time has elapsed since the cooling time characteristic was calculated, the substrate processing apparatus 1 according to the present embodiment may determine to re-calculate the cooling time characteristic of the wafer W. Also, the substrate processing apparatus 1 according to the present embodiment may determine to re-calculate the cooling time characteristic of the wafer W after maintenance of the substrate processing apparatus 1 or after part replacement.

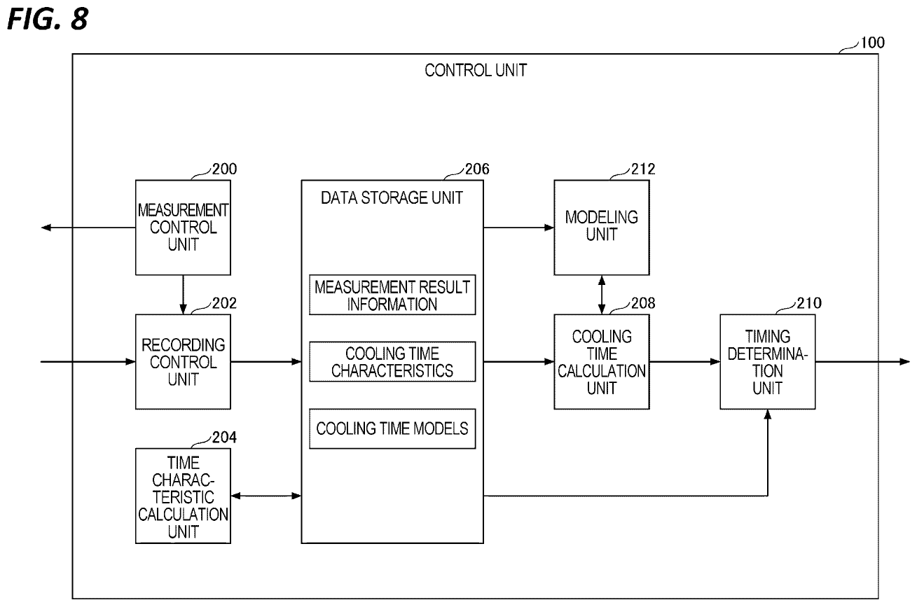

The above descriptions have been made on an example in which the cooling time characteristic is calculated for each recipe. However, there is a possibility that the cooling time characteristic may be changed depending on the arrangement of the wafers W in the wafer boat 50. Therefore, as illustrated in FIG. 8, the control unit 100 according to the present embodiment may model the relationship between the arrangement of the wafers W in the wafer boat 50 (e.g., arrangement information of the wafers W) and the cooling time characteristic, in advance, and then adjust the cooling time characteristic based on the arrangement information of the wafers W.

FIG. 8 is a functional block diagram of an example of the control unit 100 according to the present embodiment. In the configuration of the control unit 100 in FIG. 8, a modeling unit 212 is added to the control unit 100 of FIG. 5. The modeling unit 212 in FIG. 8 models the correspondence between the arrangement of the wafers W held in the wafer boat 50 and the cooling time characteristic so that the cooling time characteristic may be adjusted when the arrangement information of the wafers W is input. The modeling unit 212 adjusts the cooling time characteristic calculated by the time characteristic calculation unit 204, based on the arrangement information of the wafers W.

According to the functional block diagram of FIG. 8, since the cooling time may be adjusted depending on the arrangement of the wafers W in the wafer boat 50, it is possible to use a more accurate cooling time to estimate the cooling time until the temperature of the wafer W becomes equal to or less than the threshold value.

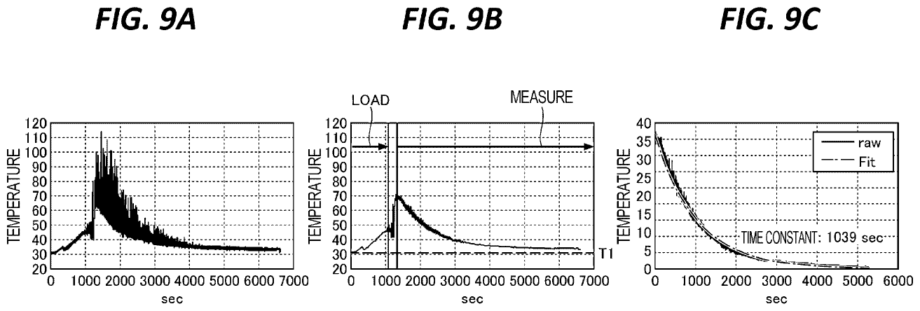

FIGS. 9A to 9C are views illustrating an example of the evaluation result of the substrate processing apparatus 1 according to the present embodiment. In the graph diagrams of FIGS. 9A to 9C, the horizontal axis indicates an elapsed time (min), and the vertical axis indicates a temperature (°C). FIG. 9A is Raw data measured by the temperature sensor 67 at the measurement position P2. Since the threshold value is set to 30° C., in the Raw data of FIG. 9A, it is possible to monitor the temperature of the wafer W up to a temperature close to a final cooling temperature.

FIG. 9B is a moving average of Raw data of FIG. 9A, and is analyzable data. FIG. 9C is obtained by performing offset correction on the moving average illustrated in FIG. 9B, with the final cooling temperature of 0 ° C. Also, FIG. 9C displays the measurement range illustrated in FIG. 9B, in an enlarged scale.

FIG. 9C illustrates the fitting result of Equation (1) in relation to the moving average of the Raw data. In FIG. 9C, for example, the calculated time constant (e.g., cooling time characteristic) is 1,039 sec.

The accuracy of the cooling time calculated by the substrate processing apparatus 1 according to the present embodiment is sufficient in the use in estimating the cooling time until the temperature of the wafer W becomes equal to or less than the threshold value after the wafer boat 50 is unloaded from the heat treatment container 82. Therefore, according to the substrate processing apparatus 1 according to the present embodiment, it is possible to provide a technique for appropriately determining the timing to start transfer of the wafers W from the wafer boat 50.

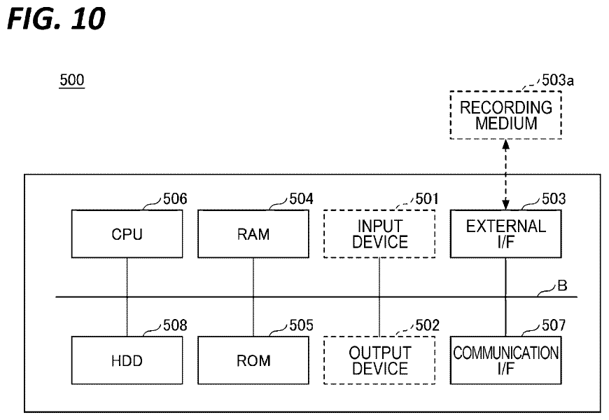

The control unit 100 may be realized by a computer with a hardware configuration illustrated in, for example, FIG. 10. FIG. 10 is a hardware configuration diagram of an example of a computer 500.

The computer 500 of FIG. 10 includes, for example, an input device 501, an output device 502, an external interface (I/F) 503, a random access memory (RAM) 504, a read only memory (ROM) 505, a central processing unit (CPU) 506, a communication I/F 507, and a hard disk drive (HDD) 508, which are connected to each other via a bus B. In another mode, the input device 501 and the output device 502 may be connected and used when necessary.

The input device 501 is, for example, a keyboard, a mouse, or a touch panel, and is used when the operator inputs an operation signal. The output device 502 is, for example, a display, and displays the results of processing performed by the computer 500. The communication I/F 507 is an interface that connects the computer 500 to a data communication network. The HDD 508 is an example of a non-volatile storage device that stores programs or data.

The external I/F 503 is an interface with an external device. The computer 500 may perform reading of a recording medium 503a such as a secure digital (SD) memory card via the external I/F 503. The computer 500 may also perform writing to the recording medium 503a such as the SD memory card via the external I/F 503.

The ROM 505 is an example of a non-volatile semiconductor memory (a storage device) in which programs and data are stored. The RAM 504 is an example of a volatile semiconductor memory (a storage device) that temporarily holds programs and data. The CPU 506 is a computing device that reads programs and data from the storage device such as the ROM 505 or the HDD 508, into the RAM 504, and executes processing so as to realize the overall control and functions of the computer 500.

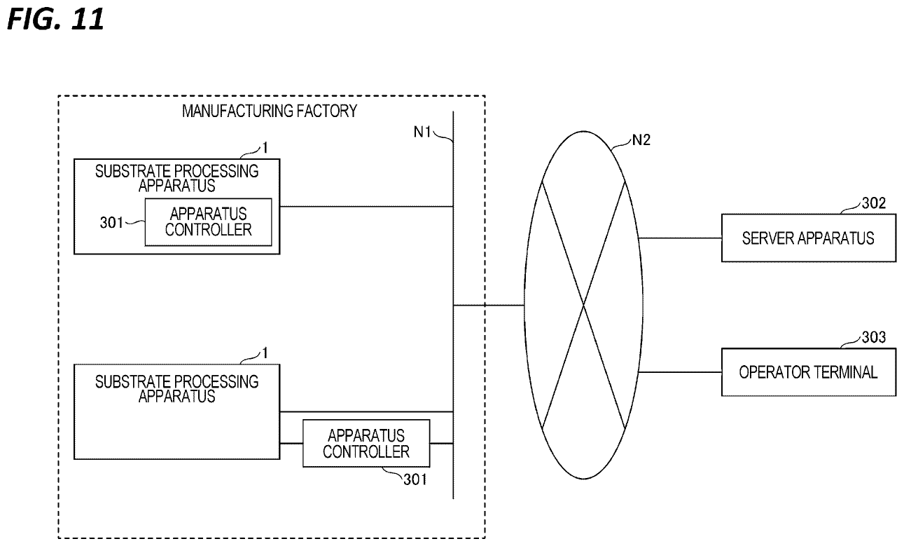

The control unit 100 executes programs through the computer 500 so as to realize various functions illustrated in FIG. 5 and FIG. 8. Also, at least a part of various functions of the control unit 100 illustrated in FIG. 5 and FIG. 8 may be provided in an apparatus controller 301, a server apparatus 302, or an operator terminal 303 illustrated in FIG. 11.

FIG. 11 is a configuration diagram of an example of a substrate processing system according to the present embodiment. The substrate processing system of FIG. 11 includes the substrate processing apparatus 1, the apparatus controller 301, the server apparatus 302, and the operator terminal 303.

The substrate processing apparatus 1 and the apparatus controller 301 are installed in a manufacturing factory. The server apparatus 302 and the operator terminal 303 may be installed in the manufacturing factory, or may be installed outside the manufacturing factory. The operator terminal 303 is, for example, a personal computer (PC) or a smartphone operated by an operator such as a person in charge of equipment or analysis of the substrate processing apparatus 1 installed in the manufacturing factory.

The substrate processing apparatus 1, the apparatus controller 301, the server apparatus 302, and the operator terminal 303 are communicatively connected via networks N1 and N2 such as the Internet or a local area network (LAN).

The substrate processing apparatus 1 is an apparatus that performs heat treatment such as film forming processing, and processes, for example, a substrate such as a wafer W. The substrate processing apparatus 1 is, for example, a semiconductor manufacturing apparatus, a heat treatment apparatus, or a film formation apparatus. The substrate processing apparatus 1 is, for example, a batch type or a single-wafer type.

The apparatus controller 301 receives an instruction for the substrate processing apparatus 1 from the operator. The apparatus controller 301 has a function of a man-machine interface that provides information on the substrate processing apparatus 1, to the operator. The apparatus controller 301 may receive information (e.g., sensor status) measured by the plurality of sensors provided in the substrate processing apparatus 1, and store the information in a storage inside or outside the devices of the substrate processing apparatus 1.

The apparatus controller 301 illustrated in FIG. 1 is provided for each substrate processing apparatus 1, but may be provided for a plurality of substrate processing apparatuses 1. The apparatus controller 301 may be provided inside the housing of the substrate processing apparatus 1, or may be provided outside the housing.

Also, the control unit 100, the apparatus controller 301, the server apparatus 302, and the operator terminal 303 are examples of the information processing apparatus that controls the substrate processing apparatus 1. The substrate processing system illustrated in FIG. 11 is an example, and it goes without saying that there are various system configuration examples depending on application or purpose. The classification of apparatuses such as the apparatus controller 301, the server apparatus 302, and the operator terminal 303 illustrated in FIG. 11 is an example. For example, in the substrate processing system illustrated in FIG. 11, various configurations are possible such as a configuration in which at least two of the apparatus controller 301, the server apparatus 302, and the operator terminal 303 are integrated, or a configuration in which the apparatus controller 301, the server apparatus 302, and the operator terminal 303 are further divided.

The substrate processing apparatus 1 of the present disclosure is not limited to the configuration illustrated in FIG. 1, and needless to say, there are various configuration examples depending on the application or purpose. The substrate processing apparatus 1 of the present disclosure may be applied to any of a single-wafer-type apparatus that processes substrates one by one, a batch-type apparatus that processes a plurality of substrates at once, and a semi-batch-type substrate processing apparatus.

According to the present disclosure, it is possible to provide a technology of appropriately determining the timing to start transfer of substrates from the substrate holder in the substrate processing apparatus.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be restricting, with the true scope and spirit being indicated by the following claims.

What is claimed is:

1. A substrate processing apparatus comprising:
a heat treatment container;
a substrate holder configured to be accommodated in the heat treatment container while holding a substrate;
a transfer device including a temperature sensor, and configured to move between a measurement position for measuring a temperature of the substrate held by the substrate holder unloaded from the heat treatment container and a standby position separated from the measurement position; and
a controller configured to control an operation of the transfer device,
wherein the controller is configured to:
move the transfer device between the measurement position and the standby position, and cause the temperature sensor to measure a temperature change of the substrate over time after the substrate holder is unloaded from the heat treatment container;
calculate, based on a measurement result of the temperature change of the substrate over time, a time characteristic of the temperature of the substrate after the substrate holder is unloaded from the heat treatment container;
calculate, based on the time characteristic of the temperature of the substrate, a cooling time until the temperature of the substrate becomes equal to or less than a threshold value after the substrate holder is unloaded from the heat treatment container; and
determine, based on the cooling time, a timing to start transfer of the substrate from the substrate holder.

2. The substrate processing apparatus according to claim 1, wherein the controller is configured to:
cause the transfer device to start the transfer of the substrates from the substrate holder when, before the cooling time is calculated, the temperature of the substrate measured by the temperature sensor becomes equal to or less than the threshold value, and
cause the transfer device to start the transfer of the substrates from the substrate holder after the cooling time is calculated and upon elapse of the cooling time.

3. The substrate processing apparatus according to claim 2, wherein the controller is configured to, when determining the timing to start the transfer of the substrates from the substrate holder based on the cooling time, not cause the temperature sensor to measure the temperature change of the substrate over time after the substrate holder is unloaded from the heat treatment container.

4. The substrate processing apparatus according to claim 2, wherein the controller is configured to, when the substrate holder is unloaded from the heat treatment container due to interruption of heat treatment in the heat treatment container, cause the transfer device to start the transfer of the substrates from the substrate holder after the temperature of the substrate measured by the temperature sensor becomes equal to or less than the threshold value.

5. The substrate processing apparatus according to claim 1, wherein the controller is configured to:
cause the temperature sensor to re-measure the temperature change of the substrate when a predetermined period of time has elapsed after calculation of the time characteristic,
re-calculate, based on a re-measurement result, the time characteristic of the temperature of the substrate after the substrate holder is unloaded from the heat treatment container, and
re-calculate, based on the re-calculated time characteristic of the temperature of the substrate, the cooling time until the temperature of the substrate becomes equal to or less than the threshold value after the substrate holder is unloaded from the heat treatment container.

6. The substrate processing apparatus according to claim 1, wherein the controller is further configured to:
model a correspondence between an arrangement of the substrate held by the substrate holder and the time characteristic of the temperature of the substrate such that the time characteristic of the temperature of the substrate is adjusted when arrangement information of the substrate held by the substrate holder is input, and
calculate, based on the adjusted time characteristic of the temperature of the substrate, the cooling time until the temperature of the substrate becomes equal to or less than the threshold value after the substrate holder is unloaded from the heat treatment container.

7. The substrate processing apparatus according to claim 1, wherein the controller is configured to:
move the transfer device to the standby position when the measurement result of the temperature sensor at the measurement position exceeds the threshold value within a first time period, and
moves the transfer device back to the measurement position after a second time period has elapsed at the standby position.

8. An information processing apparatus for controlling a substrate processing apparatus, the substrate processing apparatus including:
a heat treatment container;
a substrate holder configured to be accommodated in the heat treatment container while holding a substrate;
a transfer device including a temperature sensor, and configured to move between a measurement position for measuring a temperature of the substrate held by the substrate holder unloaded from the heat treatment container and a standby position separated from the measurement position; and
a controller configured to control an operation of the transfer device,
the information processing apparatus comprising:
measurement control circuitry configured to move the transfer device between the measurement position and the standby position, and cause the temperature sensor to measure a temperature change of the substrate over time after the substrate holder is unloaded from the heat treatment container;
time characteristic calculation circuitry configured to calculate, based on a measurement result of the temperature change of the substrate over time, a time characteristic of the temperature of the substrate after the substrate holder is unloaded from the heat treatment container;
cooling time calculation circuitry configured to calculate, based on the time characteristic of the temperature of the substrate. a cooling time until the temperature of the substrate becomes equal to or less than a threshold value after the substrate holder is unloaded from the heat treatment container; and
timing determination circuitry configured to determine, based on the cooling time, a timing to start transfer of the substrate from the substrate holder.

9. An information processing method comprising:
providing a substrate processing apparatus including:
a heat treatment container;
a substrate holder configured to be accommodated in the heat treatment container while holding a substrate;
a transfer device including a temperature sensor, and configured to move between a measurement position for measuring a temperature of the substrate held by the substrate holder unloaded from the heat treatment container and a standby position separated from the measurement position; and
a controller configured to control an operation of the transfer device;
moving the transfer device between the measurement position and the standby position, and causing the temperature sensor to measure a temperature change of the substrate over time after the substrate holder is unloaded from the heat treatment container;
calculating, based on a measurement result of the temperature change of the substrate over time, a time characteristic of the temperature of the substrate after the substrate holder is unloaded from the heat treatment container;
calculating, based on the time characteristic of the temperature of the substrate cooling time until the temperature of the substrate becomes equal to or less than a threshold value after the substrate holder is unloaded from the heat treatment container; and
determining, based on the cooling time, a timing to start transfer of the substrates from the substrate holder.
